(19) United States
(12) Patent Application Publication
(10) Pub. No.: US 2025/0234602 A1
(43) Pub. Date: Jul. 17, 2025

(54) Contact Structures in Semiconductor Devices

(71) Applicant: Taiwan Semiconductor Manufacturing Company, Ltd., Hsinchu (TW)

(72) Inventors: Chi-Cheng HUNG, Tainan City (TW); Yen-Hsung HO, Zhongli City (TW); Shan Chun YANG, Tainan City (TW); Yu-Ting LIN, Tainan City (TW); Po-Wei WANG, Taichung City (TW); Tai-Ting SU, Hsinchu City (TW)

(73) Assignee: Taiwan Semiconductor Manufacturing Company, Ltd., Hsinchu (TW)

(21) Appl. No.: 18/411,595

(22) Filed: Jan. 12, 2024

(51) Int. Cl. H01L 29/06; H01L 21/285; H01L 21/311; H01L 21/8234; H01L 27/088; H01L 29/08; H01L 29/423; H01L 29/66; H01L 29/775; H01L 29/786

(52) U.S. Cl. CPC H10D 62/118; H01L 21/28518; H01L 21/31116; H10D 30/024; H10D 30/43; H10D 30/6735; H10D 30/6757; H10D 62/151; H10D 84/013; H10D 84/0135; H10D 84/038; H10D 84/834

(57) ABSTRACT

A semiconductor device and a method of fabricating the semiconductor device are disclosed. The method includes forming a nanostructured layer on a substrate, forming a gate structure surrounding the nanostructured layer, forming a S/D region adjacent to the nanostructured layer, forming a contact opening on the S/D region, depositing a first conductive layer in the contact opening using a first deposition process, performing a plasma etch process on the first conductive layer, depositing a second conductive layer on the first conductive layer using a second deposition process different from the first deposition process, and depositing a metal layer on the second conductive layer.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with contact structures, in accordance with some embodiments.

FIGS. 1B and 1C illustrate different cross-sectional views of a semiconductor device with contact structures, in accordance with some embodiments.

FIG. 2 is a flow diagram of a method for fabricating a semiconductor device with contact structures, in accordance with some embodiments.

FIGS. 3-11 and 13-18 illustrate cross-sectional views of a semiconductor device with contact structures at various stages of its fabrication process, in accordance with some embodiments.

FIG. 12 illustrates oxygen concentration profiles in a contact structure of a semiconductor device at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

The GAA transistor structures may be patterned by any suitable method. For example, the structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistor structure.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example methods for minimizing contact resistance between contact structures and source/drain (S/D) regions in FETs (e.g., finFETs and GAA FETs). In some embodiments, a S/D region can be formed on a fin base and a contact structure can be formed on the S/D region. In some embodiments, the formation of the contact structure can include depositing a first diffusion barrier layer in a contact opening on the S/D region, depositing a second diffusion barrier layer on the first diffusion barrier layer, and depositing a conductive layer on the second diffusion barrier layer. In some embodiments, the formation of the contact structure can further include performing an oxide removal process (also referred to as a “cleaning process”) on the first diffusion barrier layer prior to depositing the second diffusion barrier layer. The oxide removal process can remove a native oxide layer and/or oxygen atoms from a top surface of the first diffusion barrier layer to reduce a concentration of oxygen atoms on the top surface of the first diffusion barrier layer to less than about 5 atomic % (e.g., about 0.1 atomic % to about 4.9 atomic %). The native oxide layer and/or the oxygen atoms on the top surface of the first diffusion barrier layer can be introduced due to a reaction between atmospheric oxygen and the material of the first diffusion barrier layer during a vacuum break between the deposition of the first and second diffusion barrier layers. The presence of the native oxide layer and/or the oxygen atoms at the interface between the first and second diffusion barrier layers can degrade the electrical conductivity between the contact structure and the S/D region. Thus, the oxide removal process can minimize the contact resistance between the contact structure and the S/D region.

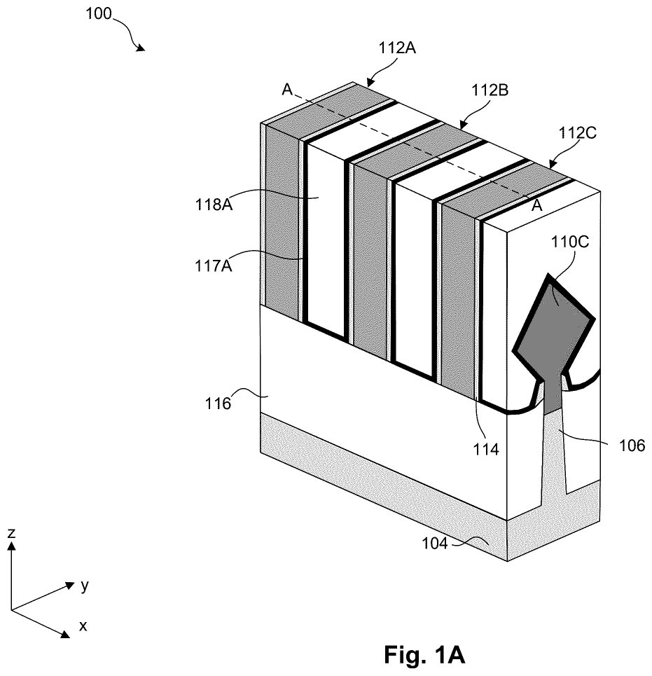

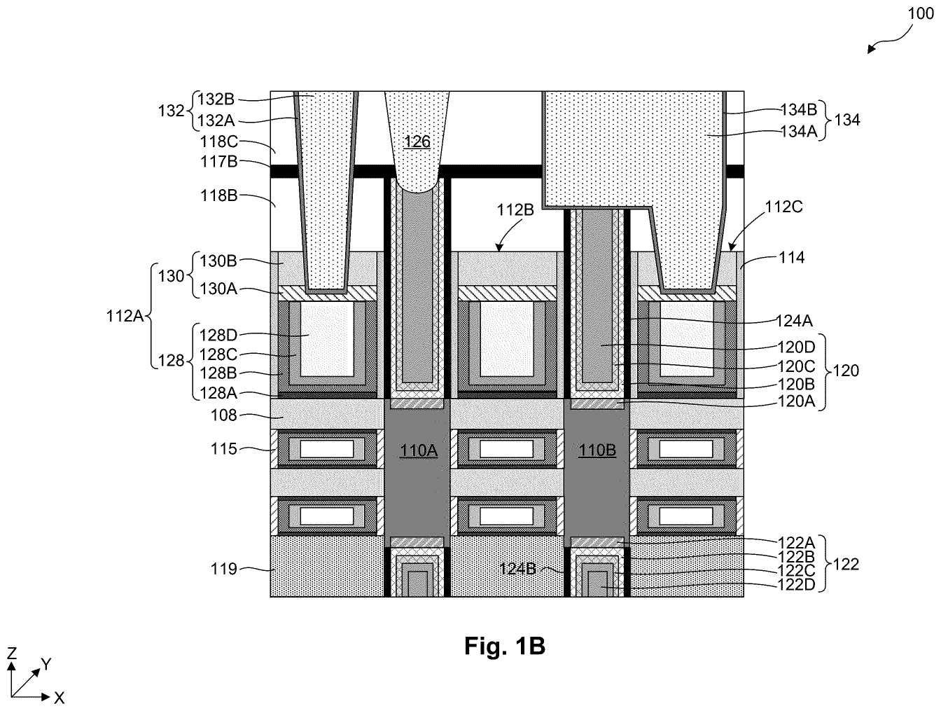

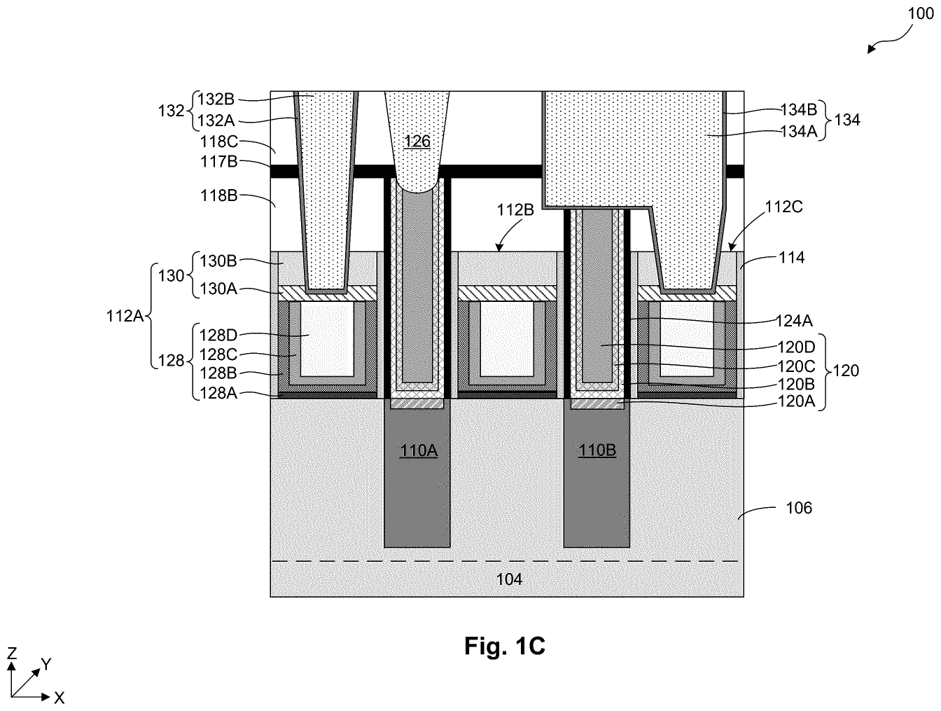

FIG. 1A illustrates an isometric view of a FET 100, according to some embodiments. FIGS. 1B and 1C illustrate different cross-sectional views of FET 100 along line A-A of FIG. 1A. In some embodiments, the cross-sectional view of FET 100 in FIG. 1B can represent a GAA FET 100 and the cross-sectional view of FET 100 in FIG. 1C can represent a finFET 100. FIGS. 1B and 1C illustrate cross-sectional views of FET 100 with additional structures that are not shown in FIG. 1A for simplicity. The discussion of elements in FIGS. 1A-1C with the same annotations applies to each other, unless mentioned otherwise.

FET 100 can be formed on a substrate 104. There may be other FETs and/or structures (e.g., isolation structures) formed on substrate 104. In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic).

Referring to FIGS. 1A and 1B, in some embodiments, FET 100 can include (i) a fin or sheet base 106 disposed on substrate 104, (ii) nanostructured channel regions 108, (iii) S/D regions 110A-110C (S/D region 110C visible in FIG. 1A; 110A-110B visible in FIG. 1B), (iv) gate structures 112A-112C surrounding nanostructured channel regions 108, (v) gate spacers 114, (vi) inner spacers 115, (vii) etch stop layers (ESLs) 117A and 117B (ESL 117B not shown in FIG. 1A and ESL 117A not shown in FIG. 1B for simplicity), (viii) interlayer dielectric (ILD) layers 118A-118C and 119 (ILD layers 118B and 118C not shown in FIG. 1A for simplicity; shown in FIG. 1B), (ix) S/D contact structures 120 and 122, (x) dielectric barrier layers 124A and 124B, (xi) a via structure 126, (xii) a gate contact structure 132, and (xiii) a merged via-contact structure 134. Each of S/D regions 110A-110C may refer to a source or a drain, individually or collectively dependent upon the context.

In some embodiments, fin or sheet base 106 can include a material similar to substrate 104. Fin or sheet base 106 can have elongated sides extending along an X-axis. In some embodiments, substrate 104 and fin or sheet base 106 can be replaced with S/D contact structures 122 and ILD layer 119, as described below with reference to FIGS. 1B, 17, and 18.

In some embodiments, nanostructured channel regions 108 can be in the form of nanosheets, nanowires, nanorods, nanotubes, or other suitable nanostructured shapes. Nanostructured channel regions 108 can include semiconductor materials similar to or different from substrate 104. In some embodiments, nanostructured channel regions 108 can include Si, silicon arsenide (SiAs), silicon phosphide (SiP), silicon carbide (SiC), silicon carbon phosphide (SiCP), silicon germanium (SiGe), silicon germanium boron (SiGeB), germanium boron (GeB), silicon germanium stannum boron (SiGeSnB), a III-V semiconductor compound, or other suitable semiconductor materials. Though rectangular cross-sections of nanostructured channel regions 108 are shown, nanostructured channel regions 108 can have cross-sections of other geometric shapes (e.g., circular, elliptical, triangular, or polygonal). As used herein, the term “nanostructured” defines a structure, layer, and/or region as having a horizontal dimension (e.g., along an X- and/or Y-axis) and/or a vertical dimension (e.g., along a Z-axis) less than about 100 nm, for example about 90 nm, about 50 nm, about 10 nm, or other values less than about 100 nm.

Each of S/D regions 110A-110C can include an epitaxially-grown semiconductor material, such as Si, and n-type dopants, such as phosphorus and other suitable n-type dopants, for n-type FET 100 and can include an epitaxially-grown semiconductor material, such as Si and SiGe, and p-type dopants, such as boron and other suitable p-type dopants for p-type FET 100.

S/D contact structures 120 can be disposed on front-side surfaces of S/D regions 110A-110C. In some embodiments, each S/D contact structures 120 can have a width of about 10 nm to about 20 nm and a height of about 35 nm to about 50 nm to provide adequate electrical conductivity between S/D regions 110A-110C and overlying interconnect structures, such as via structure 126 and merged via-contact structures 134. In some embodiments, each S/D contact structures 120 can include (i) a silicide layer 120A, (ii) a first diffusion barrier layer 120B (also referred to as “first conductive barrier layer 120B”) disposed on silicide layer 120A, (iii) a second diffusion barrier layer 120C (also referred to as “second conductive barrier layer 120C”) disposed on first diffusion barrier layer 120B, and (iv) a contact plug 120D disposed on second diffusion barrier layer 120C. Silicide layer 120A can be disposed in S/D regions 110A-110C and can have a thickness of about 1 nm to about 8 nm along a Z-axis. In some embodiments, silicide layers 120A in n-type FET 100 can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ytterbium silicide (YbₓSi_{y}), europium silicide (EuₓSi_{y}), thorium silicide (ThₓSi_{y}), other suitable metal silicide materials, or a combination thereof. In some embodiments, silicide layers 120A in p-type FET 100 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof.

In some embodiments, first diffusion barrier layers 120B can be disposed directly on silicide layers 120A and second diffusion barrier layers 120C can be disposed directly on first diffusion barrier layers 120B. In some embodiments, first and second diffusion barrier layers 120B and 120C can be configured to prevent or minimize the diffusion of oxygen atoms from ILD layer 118B into contact plugs 120D. The oxygen atoms can oxidize the material of contact plugs 120D and reduce the electrical conductivity of S/D contact structures 120. In addition, first and second diffusion barrier layers 120B and 120C can be configured to prevent or minimize the diffusion of metal atoms (e.g., cobalt atoms) from contact plugs 120D into gate structures 112A-112C. The diffusion of metal atoms can degrade the performance of gate structures 112A-112C. In some embodiments, silicide layers 120A, first diffusion barrier layers 120B, and second diffusion barrier layers 120C can include the same metal, such as titanium and tantalum. In some embodiments, silicide layers 120A can include TiSi₂ or TaSi₂, first diffusion barrier layers 120B can include titanium silicon nitride (TiSiN) or tantalum silicon nitride (TaSiN), and second diffusion barrier layers 120C can include titanium nitride (TiN) or tantalum nitride (TaN). First and second diffusion barrier layers 120B and 120C can be electrically conductive.

In some embodiments, the concentrations of oxygen atoms at the interface between the first and second diffusion barrier layers 120B and 120C can be less than about 5 atomic % (e.g., about 0.1 atomic % to about 4.9 atomic %) for adequate performance of FET 100. Oxygen concentration higher than 5 atomic % at the interface between the first and second diffusion barrier layers 120B and 120C can increase the electrical resistance between contact plugs 120D and S/D regions 110A-110C and degrade the performance of FET 100. In some embodiments, sidewall portions of each first and second diffusion barrier layers 120B and 120C can have a thickness of about 0.5 nm to about 1.5 nm along an X-axis and a Y-axis, and bottom portions of each first and second diffusion barrier layers 120B and 120C can have a thickness of about 0.5 nm to about 1.5 nm along a Z-axis. Within these ranges of thicknesses, first and second diffusion barrier layers 120B and 120C can adequately prevent or minimize the diffusion of oxygen atoms and metal atoms while minimizing the electrical resistance of S/D contact structures 120. In some embodiments, the bottom portions of each first and second diffusion barrier layers 120B and 120C can be thicker than the sidewall portions of each first and second diffusion barrier layers 120B and 120C.

In some embodiments, contact plugs 120D can be disposed directly on second diffusion barrier layers 120C and can be surrounded by first and second diffusion barrier layers 120B and 120C. In some embodiments, contact plugs 120D can include conductive materials with low resistivity (e.g., resistivity of about 50μΩ-cm, about 40μΩ-cm, about 30μΩ-cm, about 20 μΩ-cm, or about 10 μΩ-cm), such as cobalt (Co), tungsten (W), ruthenium (Ru), aluminum (Al), molybdenum (Mo), iridium (Ir), nickel (Ni), Osmium (Os), rhodium (Rh), other suitable conductive materials with low resistivity, and a combination thereof.

In some embodiments, S/D contact structures 122 can be disposed on back-side surfaces of S/D regions 110A-110C. In some embodiments, each S/D contact structures 122 can have a width of about 10 nm to about 20 nm and a height of about 35 nm to about 50 nm for providing adequate electrical conductivity between S/D regions 110A-110C and underlying back-side power rails (not shown). In some embodiments, each S/D contact structures 122 can include (i) a silicide layer 122A, (ii) a first diffusion barrier layer 122B disposed on silicide layer 120A, (iii) a second diffusion barrier layer 122C disposed on first diffusion barrier layer 122B, and (iv) a contact plug 122D disposed on second diffusion barrier layer 122C. The discussion of silicide layer 120A, first diffusion barrier layer 120B, second diffusion barrier layer 120C, and contact plug 120D applies to silicide layer 122A, first diffusion barrier layer 122B, second diffusion barrier layer 122C, and contact plug 122D, unless mentioned otherwise. The first and second diffusion barrier layers 122B and 122C can be configured to prevent or minimize the diffusion of oxygen atoms from ILD layer 119 into contact plugs 122D.

In some embodiments, each S/D contact structure 120 can be surrounded by dielectric barrier layer 124A and each S/D contact structure 122 can be surrounded by dielectric barrier layer 124B. Similar to first and second diffusion barrier layers 120B and 120C, dielectric barrier layers 124A can be configured to prevent or minimize the diffusion of oxygen atoms from ILD layer 118B into contact plugs 120D and to prevent or minimize the diffusion of metal atoms from contact plugs 120D into gate structures 112A-112C. Similar to first and second diffusion barrier layers 122B and 122C, dielectric barrier layers 124B can be configured to prevent or minimize the diffusion of oxygen atoms from ILD layer 119 into contact plugs 122D. In some embodiments, dielectric barrier layers 124A and 124B can include oxygen-free dielectric nitride layers (e.g., SiN layers), oxygen-free dielectric carbide layers (e.g., silicon carbide (SiC) layers), or oxygen-free carbon nitride layers (e.g., silicon carbon nitride (SiCN) layers).

S/D contact structure 120 on S/D region 110A can electrically connect to overlying interconnect structures (not shown), power supplies (not shown), and/or other elements of FET 100 through via structure 126. Via structure 126 can be disposed in S/D contact structure 120 and can include conductive materials, such as Ru, W, Ni, Al, Mo, Ir, Os, and other suitable conductive materials. In some embodiments, the conductive materials of via structure 126 is formed by a bottom-up approach, and as a result, via structure 126 can be formed without adhesion layers (also referred to as “liners” or “glue layers”) along the sidewalls of via structure 126. In some embodiments, bottom surface of via structure 126 can have a curved profile to increase the contact area between via structure 126 and contact plug 120D, and consequently decrease the contact resistance between via structure 126 and contact plug 120D. In some embodiments, via structure 126 can have a diameter (or width) of about 11 nm to about 17 nm along an X-axis and a height of about 15 nm to about 35 nm along a Z-axis to provide adequate contact area and electrical conductivity between S/D contact structure 120 and overlying interconnect structures (not shown) without compromising device size and manufacturing cost.

Each of gate structures 112A-112C can be a multi-layered structure and can surround nanostructured channel regions 108 for which gate structures 112A-112C can be referred to as “GAA structures.” In some embodiments, each of gate structures 112A-112C can include a gate stack 128 and a gate capping structure 130. In some embodiments, gate stack 128 can include (i) an interfacial oxide (IL) layer 128A, (ii) a high-k (HK) gate dielectric layer 128B disposed on IL layer 128A, (iii) a work function metal (WFM) layer 128C disposed on HK gate dielectric layer 128B, and (iv) a gate metal fill layer 128D disposed on WFM layer 128C.

In some embodiments, IL layer 128A can include silicon oxide (SiO₂), silicon germanium oxide (SiGeOₓ), germanium oxide (GeOₓ), or other suitable oxide materials. In some embodiments, HK gate dielectric layer 128B can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium silicate (ZrSiO₂), or other suitable high-k dielectric materials. In some embodiments, WFM layer 128C can include titanium aluminum (TiAl), titanium aluminum carbide (TiAlC), tantalum aluminum (TaAl), tantalum aluminum carbide (TaAlC), Al-doped Ti, Al-doped TiN, Al-doped Ta, Al-doped TaN, or other suitable Al-based materials for n-type FET 100. In some embodiments, WFM layer 128C can include substantially Al-free (e.g., with no Al) Ti-based or Ta-based nitrides or alloys, such as titanium nitride (TiN), titanium silicon nitride (TiSiN), titanium gold (Ti—Au) alloy, titanium copper (Ti—Cu) alloy, tantalum nitride (TaN), tantalum silicon nitride (TaSiN), tantalum gold (Ta—Au) alloy, and tantalum copper (Ta—Cu) for p-type FET 100. In some embodiments, gate metal fill layer 128D can include a conductive material, such as W, Ti, Ru, Mo, Co, Al, Ir, Ni, metal alloys, and a combination thereof.

In some embodiments, gate capping structure 130 can include a conductive gate cap 130A disposed on gate stack 128 and an insulating gate cap 130B disposed on conductive gate cap 130A.

Conductive gate cap 130A can provide a conductive interface between gate metal fill layers 128D and overlying contact structures (e.g., gate contact structure 132 and merged via-contact structure 134) without forming the contact structures directly on or in gate metal fill layers 128D. The contact structures are not formed directly on or in gate metal fill layers 128D to prevent contamination by any of the processing materials used in the formation of the contact structures. Contamination of gate metal fill layer 128D can lead to the degradation of device performance. Thus, with the use of conductive gate cap 130A, gate structures 112A-112C can be electrically connected to the contact structures without compromising the integrity of gate structures 112A-112C. In some embodiments, conductive gate cap 130A can include a conductive material, such as W, Ru, Mo, Co, or other suitable conductive materials.

Insulating gate cap 130B can protect the underlying conductive gate cap 130A and gate stack 128 from structural and/or compositional degradation during subsequent processing of FET 100. In some embodiments, insulating gate cap 128B can include a nitride material, such as SiN, and can have a thickness of about 2 nm to about 10 nm for adequate protection of the underlying conductive gate cap 130A and gate stack 128.

In some embodiments, gate structures 112A-112C can be electrically isolated from adjacent S/D regions 110A-110C and from S/D contact structure 120 by gate spacers 114 and inner spacers 115. In some embodiments, gate spacers 114 and inner spacers 115 can include insulating materials, such as SiOₓ, SiN, silicon oxynitride (SiON), silicon oxycarbide (SiOC), SiCN, silicon oxycarbon nitride (SiOCN), and other suitable insulating materials.

In some embodiments, gate contact structure 132 can include a liner 132A and a contact plug 132B disposed on liner 132A. In some embodiments, liner 132A can include a nitride material, such as TiN, and contact plug 132B can include a conductive material similar to via 126. In some embodiments, liner 132A can include TiN and contact plug 132B can include W. In some embodiments, liner 132A can include TaN and contact plug 132B can include Ru.

In some embodiments, a merged via-contact structure 134 can be disposed on S/D region 110B and gate structure 112C. Merged via-contact structure 134 can electrically connect S/D region 110B and gate structure 112C to each other and with overlying interconnect structures (not shown) when FET 100 is formed in a logic device area and/or in a static random access memory (SRAM) device area of an integrated circuit (not shown). Merged via-contact structure 134 can include a liner 134A and a contact plug 134B disposed on liner 134A. In some embodiments, liner 134A and contact plug 134B can include material similar to liner 132A and contact plug 132B, respectively.

In some embodiments, each of STI regions 116, ESL 117A and 117B, and ILD layers 118A-118C and 119 can include an insulating material, such as SiO₂, SiN, SiON, SiOC, SiCN, SiOCN, and SiGeOₓ.

Referring to FIG. 1C, in some embodiments, FET 100 can be a finFET, instead of GAA FET, and can have fin structures 106 instead of nanostructured channel regions 108 and fin bases 108. FinFET can have gate structures 112A-112C disposed on fin structures 106, which can have fin regions to function as channel regions.

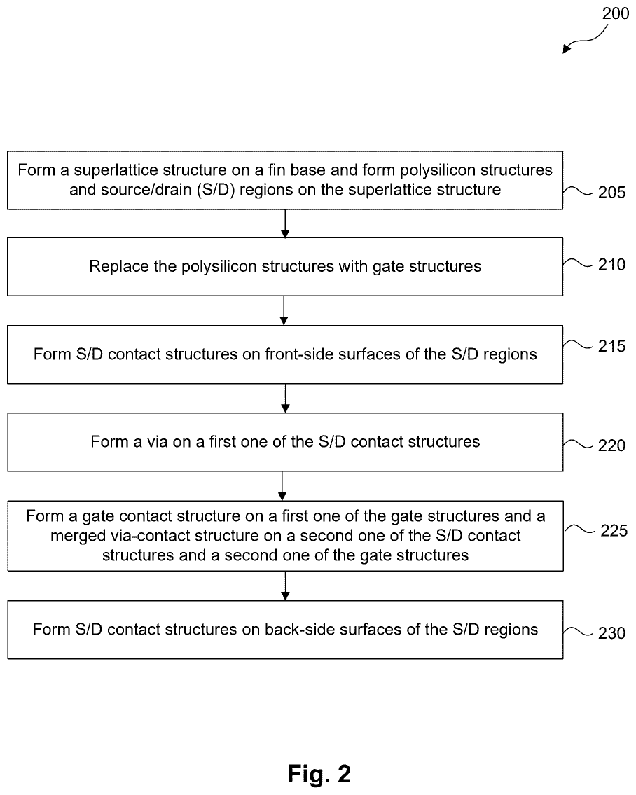

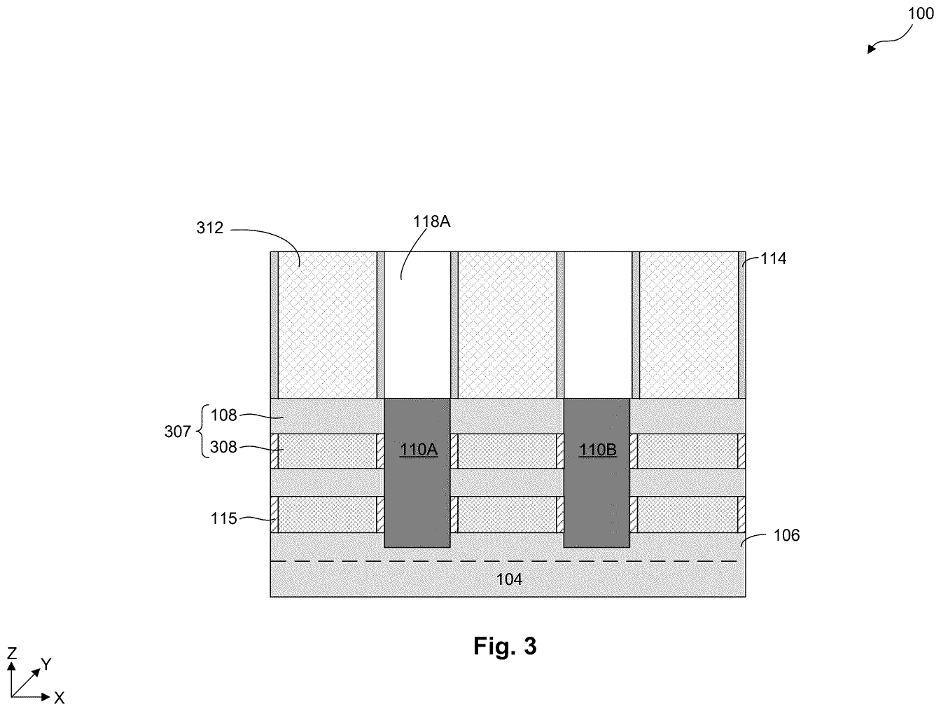

FIG. 2 is a flow diagram of an example method 200 for fabricating FET 100 with cross-sectional view of FIG. 1B, according to some embodiments. For illustrative purposes, the operations illustrated in FIG. 2 will be described with reference to the example fabrication process for fabricating FET 100 as illustrated in FIGS. 3-18. FIGS. 3-11 and 13-18 are cross-sectional views of FET 100 along line A-A of FIG. 1A at various stages of fabrication, according to some embodiments. Operations can be performed in a different order or not performed depending on specific applications. It should be noted that method 200 may not produce a complete FET 100. Accordingly, it is understood that additional processes can be provided before, during, and after method 200, and that some other processes may only be briefly described herein. The discussion of elements in FIGS. 1A, 1B, and 3-18 with the same annotations applies to each other, unless mentioned otherwise.

Referring to FIG. 2, in operation 205, a superlattice structure is formed on a fin base, and polysilicon structures and S/D regions are formed on the superlattice structure. For example, as described with reference to FIG. 3, superlattice structure 307 is formed on fin base 106, polysilicon structures 312 are formed on superlattice structure 307, and S/D regions 110A-110C are formed in superlattice structure 307. Superlattice structure 307 can include nanostructured layers 108 and 308 arranged in an alternating configuration. In some embodiments, nanostructured layers 108 and 308 include materials different from each other. Nanostructured layers 308 are also referred to as “sacrificial layers 308.” During subsequent processing, polysilicon structures 312 and sacrificial layers 308 can be replaced in a gate replacement process to form gate structures 112A-112C. In some embodiments, inner spacers 115 can be formed after the formation of polysilicon structures 312 and prior to the formation of S/D regions 110A-110C. After the formation of S/D regions 110A-110C, ESL 117A (shown in FIG. 1A; not shown in FIGS. 3-11 and 13-18 for simplicity) and ILD layer 118A can be formed, as shown in FIG. 3.

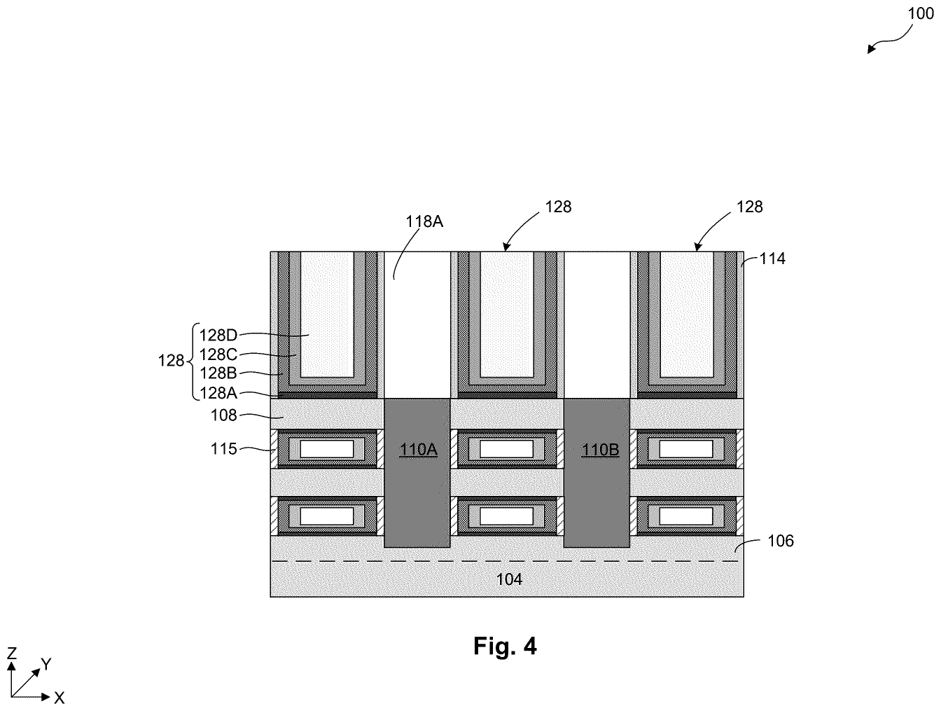

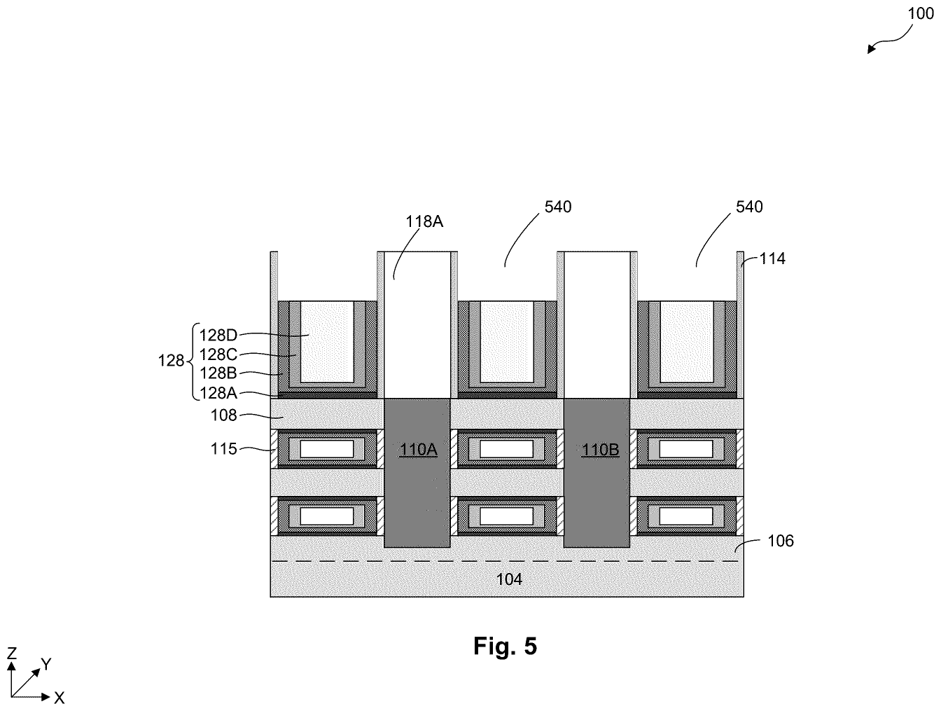

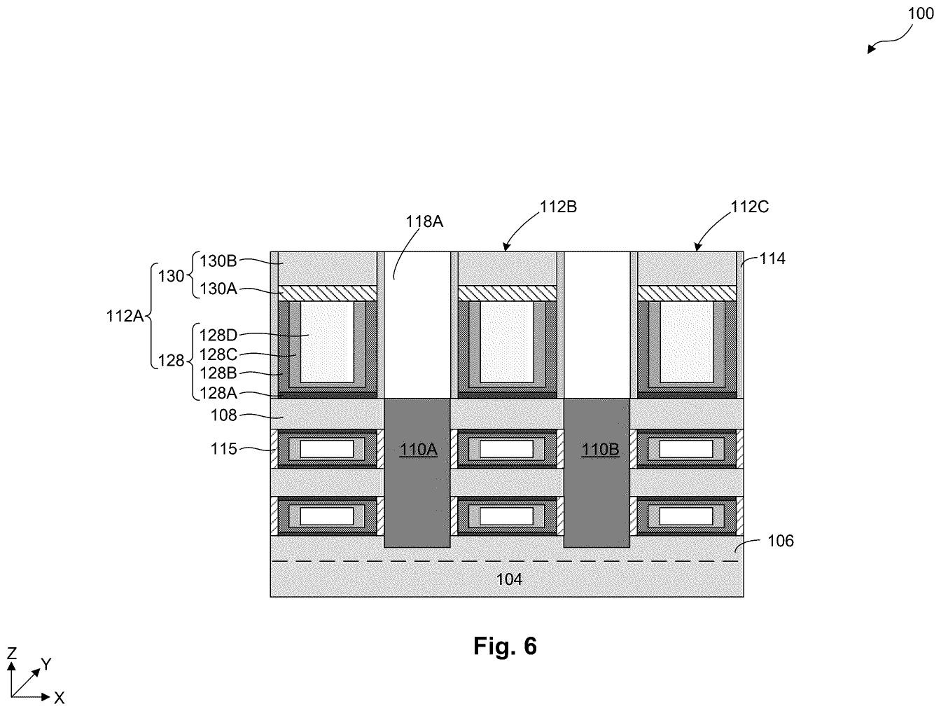

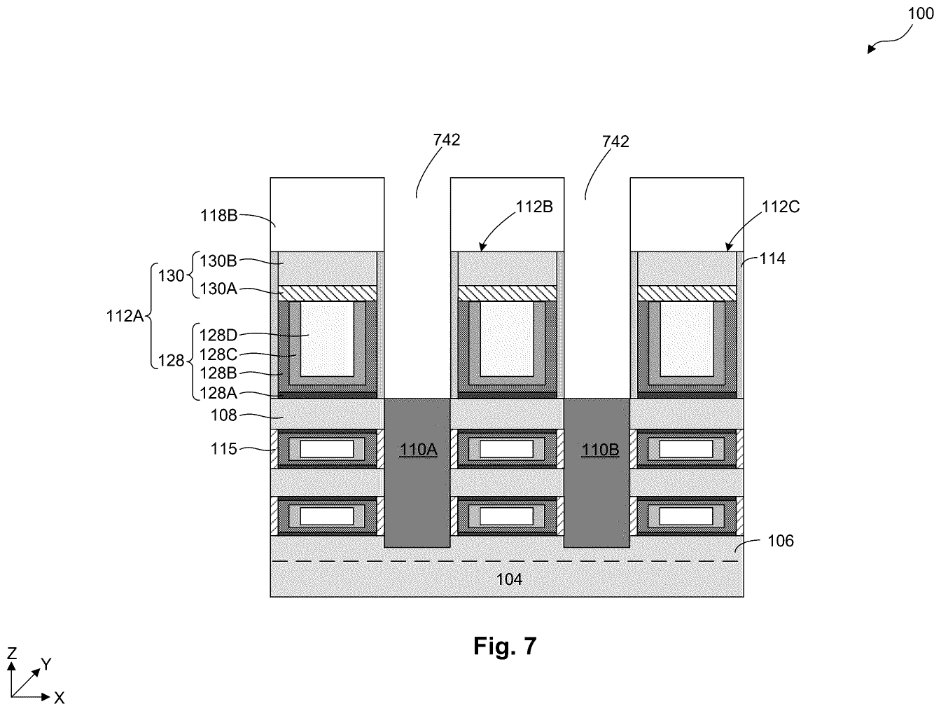

Referring to FIG. 2, in operation 210, the polysilicon structures and sacrificial layers of the superlattice structure are replaced with gate structures. For example, as described with reference to FIGS. 4-6, polysilicon structures 312 and sacrificial layers 308 are replaced with gate structures 112A-112C. The formation of gate structures 112A-112C can include sequential operations of (i) removing polysilicon structures 312 and sacrificial layers 308, (ii) forming gate stacks 128 on nanostructured layers 108, as shown in FIG. 4, (ii) etching gate stacks 128 to form gate cap openings 540, as shown in FIG. 5, and (iv) forming gate capping structures 130 on gate stacks 128, as shown in FIG. 6. After the formation of gate structures 112A-112C, ILD layer 118B can be formed, as shown in FIG. 7.

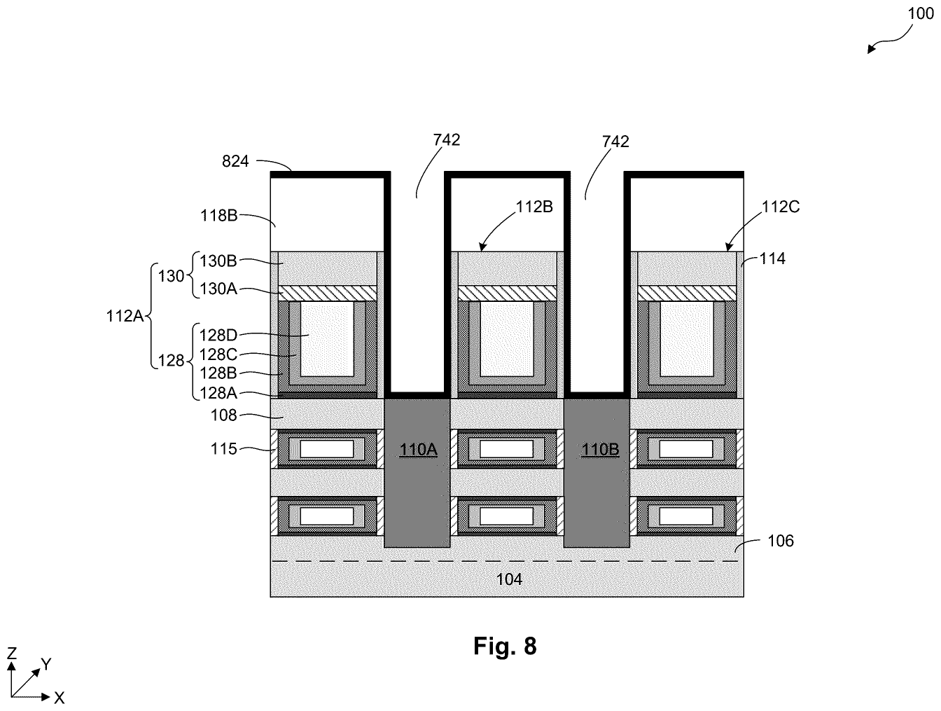

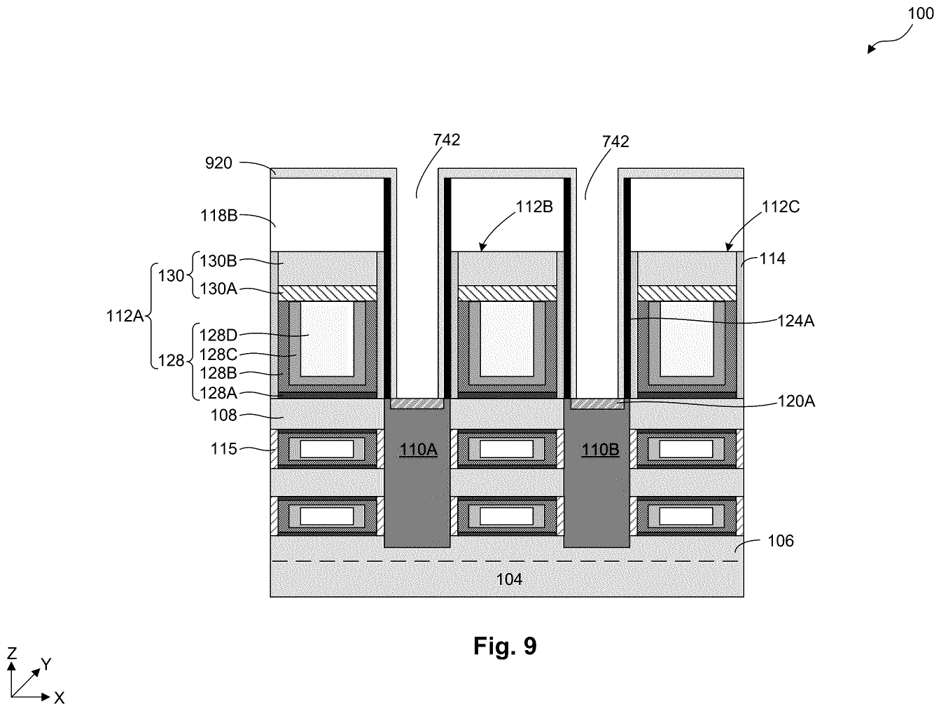

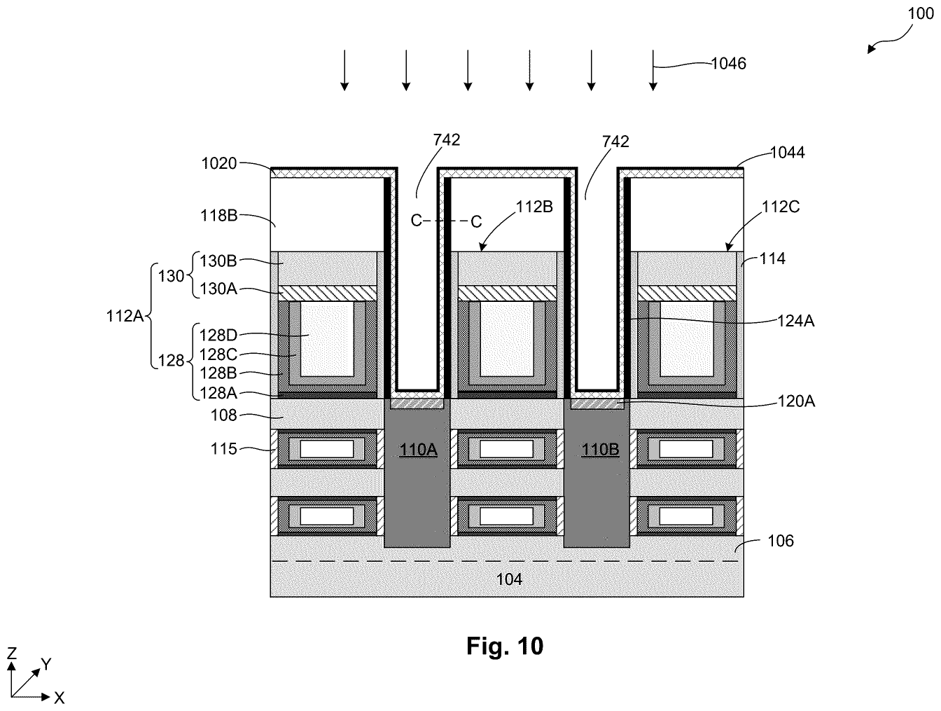

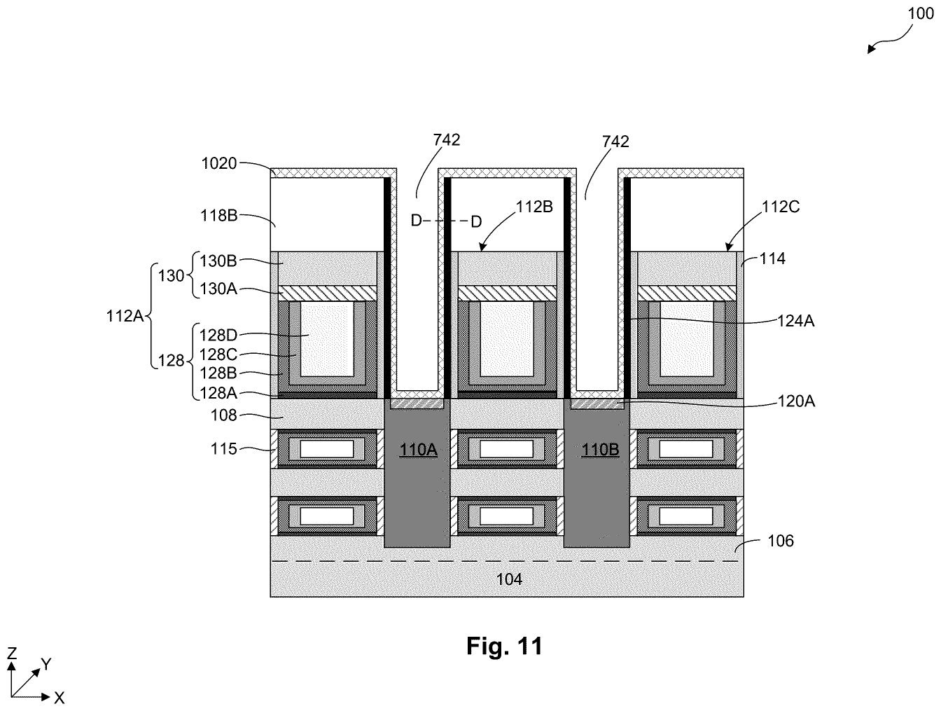

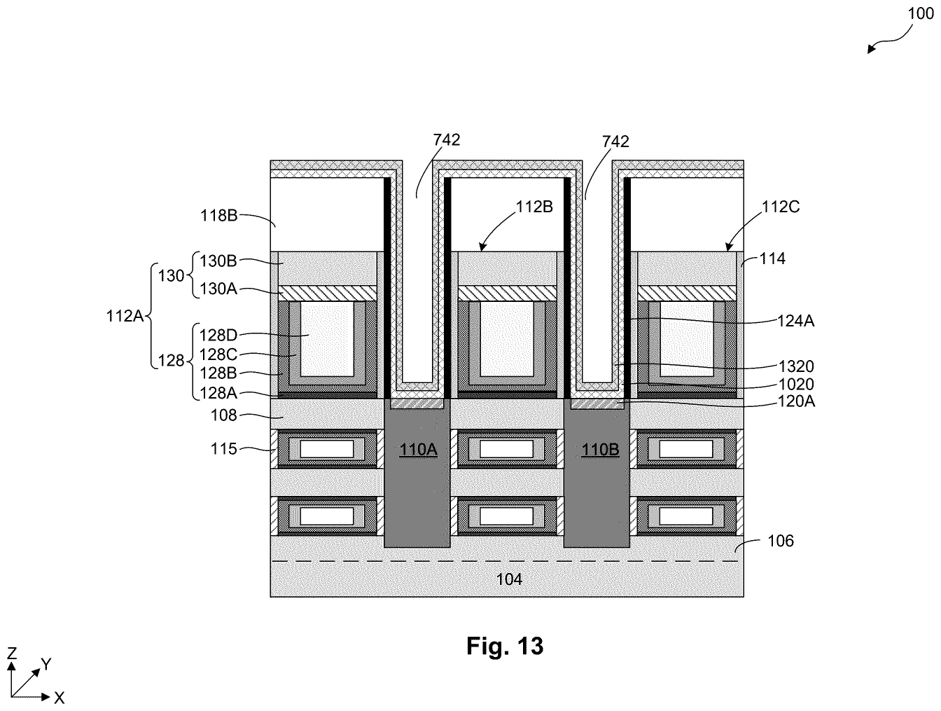

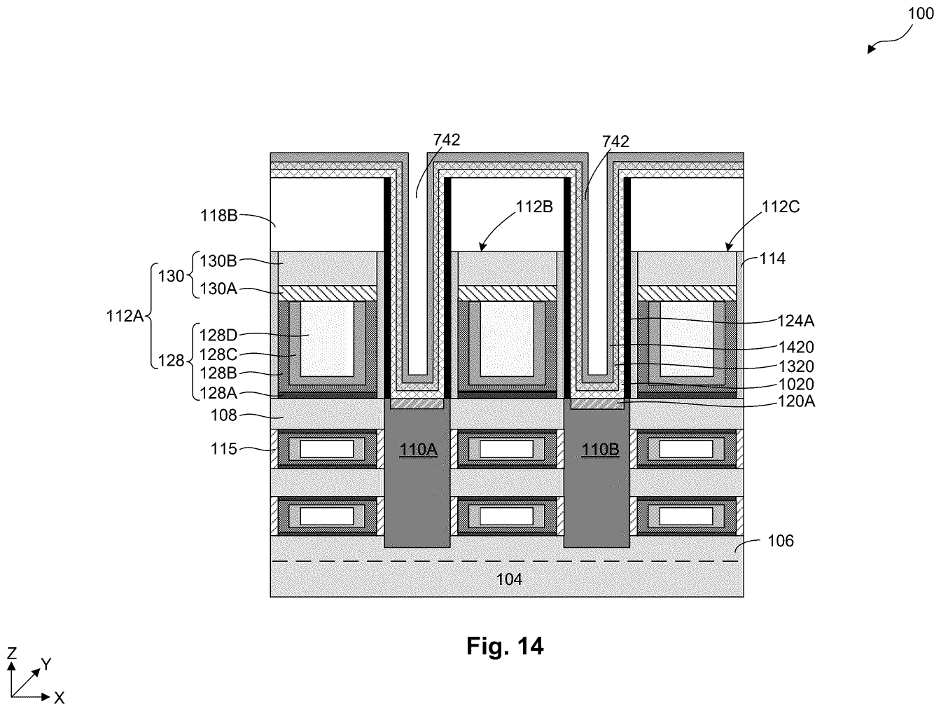

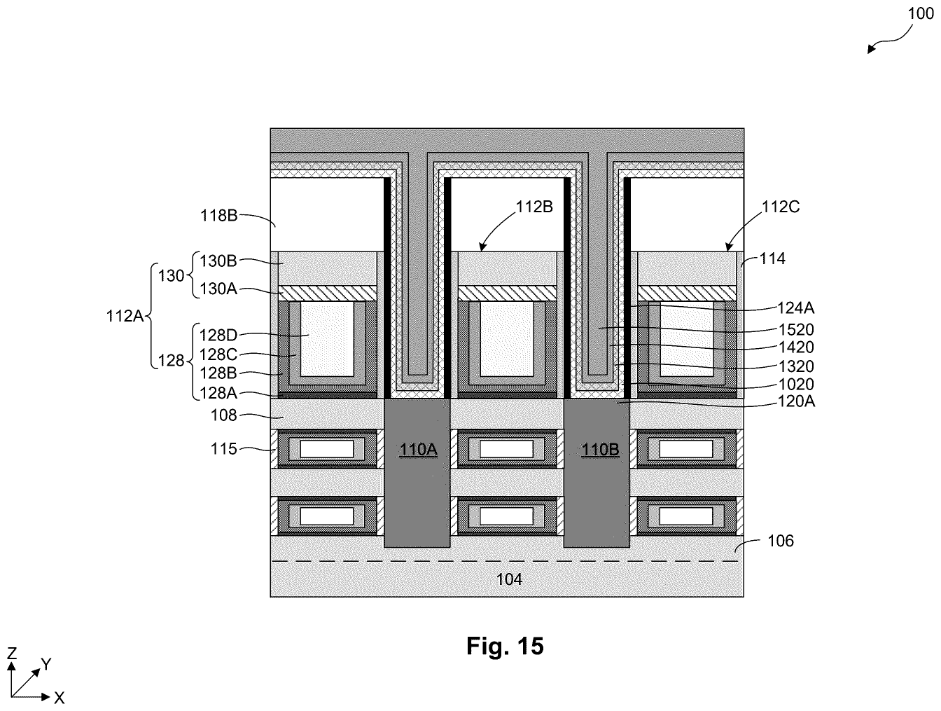

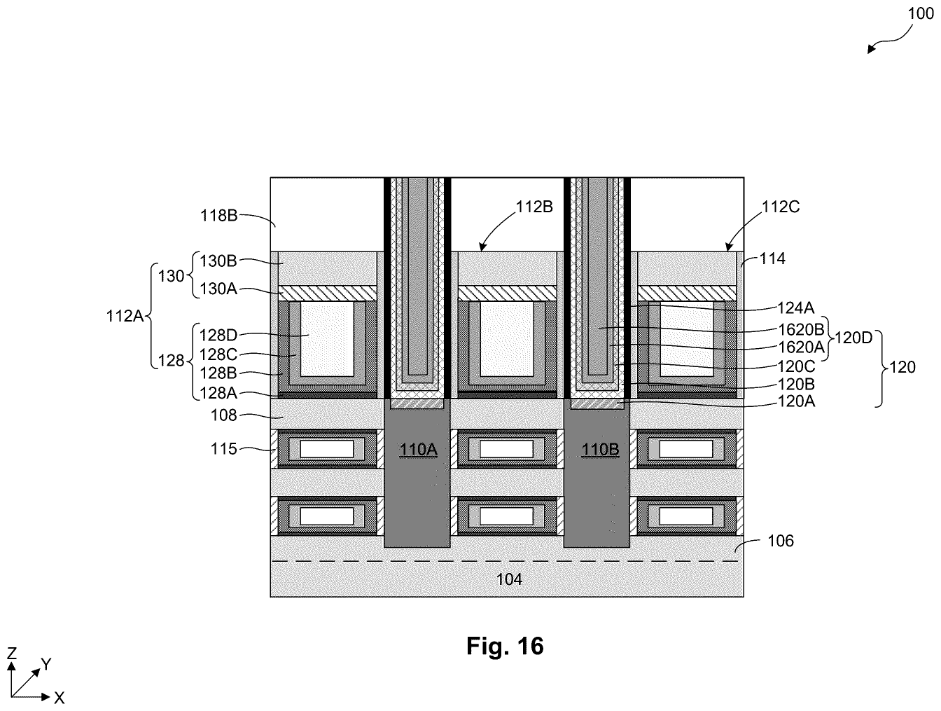

Referring to FIG. 2, in operation 215, S/D contact structures are formed on front-side surfaces of the S/D regions. For example, as described with reference to FIGS. 7-16, S/D contact structures 120 are formed on S/D regions 110A and 110B. The formation of S/D contact structures can include sequential operations of (i) forming S/D contact openings 742, as shown in FIG. 7, (ii) depositing a dielectric layer 824 on the structure of FIG. 7 to form the structure of FIG. 8, (iii) performing a chemical mechanical polishing (CMP) process on dielectric layer 824 to form dielectric barrier layer 124A, as shown in FIG. 9, (iv) forming silicide layers 120A, as shown in FIG. 9, (v) depositing a first conductive nitride layer 1020 (e.g., a TiN layer or a TaN layer) on the structure of FIG. 9 to form the structure of FIG. 10, (vi) performing an oxide removal process (also referred to as an “an oxygen removal process” or “a cleaning process”) on the structure of FIG. 10 to remove a native oxide layer 1044 and/or oxygen atoms from exposed surfaces of first conductive nitride layer 1020 and form the structure of FIG. 11, (vii) depositing a second conductive nitride layer 1320 (e.g., a TiN layer or a TaN layer) on the structure of FIG. 11 to form the structure of FIG. 13, (viii) depositing a first metal layer 1420 (e.g., a Co layer) on the structure of FIG. 13 using a CVD or an ALD process to form the structure of FIG. 14, (ix) depositing a second metal layer 1520 (e.g., a Co layer) on the structure of FIG. 14 using an electroplating process to form the structure of FIG. 15, and (x) performing a CMP process on the structure of FIG. 15 to form S/D contact structures 120, as shown in FIG. 16.

In some embodiments, depositing first conductive nitride layer 1020 can include depositing a TiN layer or a TaN using a chemical vapor deposition (CVD) process with a Ti or a Ta precursor gas and an ammonia (NH₃) gas. The CVD process can be used to form first conductive nitride layer 1020 as the NH₃ gas can react with Ti or Ta precursor gas to form TiN or TaN layer as first conductive nitride layer 1020 and at the same time can remove residual metal (e.g., Ti) layers 920 (shown in FIG. 9) from surfaces of dielectric barrier layers 124A. The residual metal layers 920 can be portions of a metal layer (not shown) that is deposited during the formation of metal silicide layers 120A. In some embodiments, silicon atoms of dielectric barrier layers 124A can diffuse into or react with TiN or TaN layer of first conductive nitride layer 1020 to form TiSiN or TaSiN. First conductive nitride layer 1020 can form first diffusion barrier layers 120B in subsequent processing.

In some embodiments, depositing second conductive nitride layer 1320 can include depositing a TiN layer or a TaN using an atomic layer deposition (ALD) process. Second conductive nitride layer 1320 can form second diffusion barrier layers 120C in subsequent processing. The deposition processes of first and second conductive nitride layers 1020 and 1320 are ex-situ processes and as a result, a vacuum break is introduced between the deposition processes of first and second conductive nitride layers 1020 and 1320. Due to the vacuum break, native oxide layer 1044 and/or the oxygen atoms can be introduced on the exposed surfaces of first conductive nitride layer 1020.

In some embodiments, the oxide removal process to remove native oxide layer 1044 and/or the oxygen atoms can include performing a plasma etch process with hydrogen radicals in a processing chamber with a gas mixture 1146 of hydrogen and nitrogen at a high temperature of about 350° C. to about 450° C. and at a bias power of about 0.5 W to about 5 W. In some embodiments, the concentration ratio of hydrogen to nitrogen in gas mixture 1146 can be about 4:1 to about 6:1 for adequate removal of native oxide layer 1044 and/or the oxygen atoms and to reduce the concentration of oxygen atoms on the exposed surfaces of first conductive nitride layer 1020 to less than about 5 atomic % (e.g., about 0.1 atomic % to about 4.9 atomic %). In some embodiments, the oxide removal process can include supplying the hydrogen gas at a flow rate of about 30 sccm to about 50 sccm and the nitrogen gas at a flow rate of about 5 sccm to about 20 sccm to achieve the concentration ratio of hydrogen to nitrogen in gas mixture 1146 of about 4:1 to about 6:1.

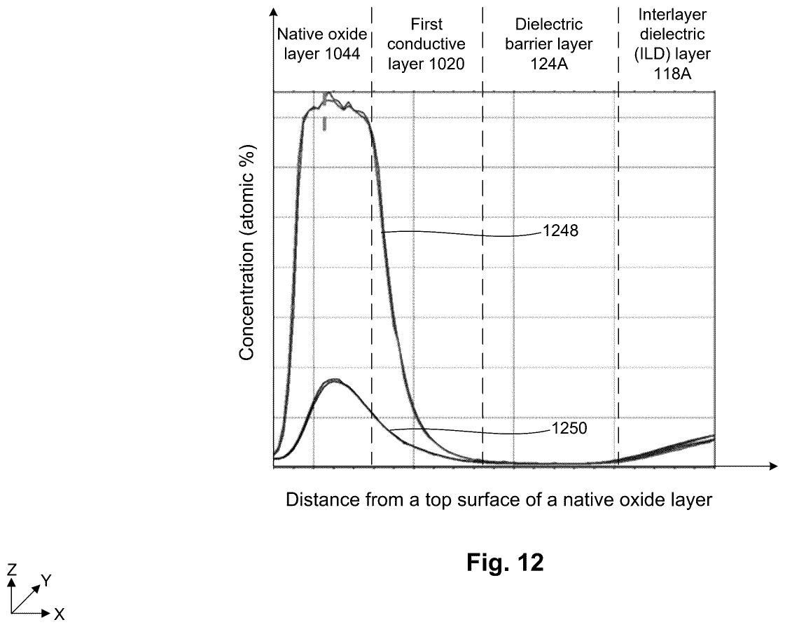

The reduction in the concentration of oxygen atom on the exposed surfaces of first conductive nitride layer 1020 after performing the oxide removal process is illustrated in FIG. 12. FIG. 12 illustrates a concentration profile 1248 of oxygen atoms across line C-C of FIG. 10 prior to performing the oxide removal process and a concentration profile 1250 of oxygen atoms across line D-D of FIG. 11 after performing the oxide removal process. In some embodiments, the peak concentration of concentration profile 1250 can be less than about 5 atomic % and can be about 80% to about 90% lower than the peak concentration of concentration profile 1248.

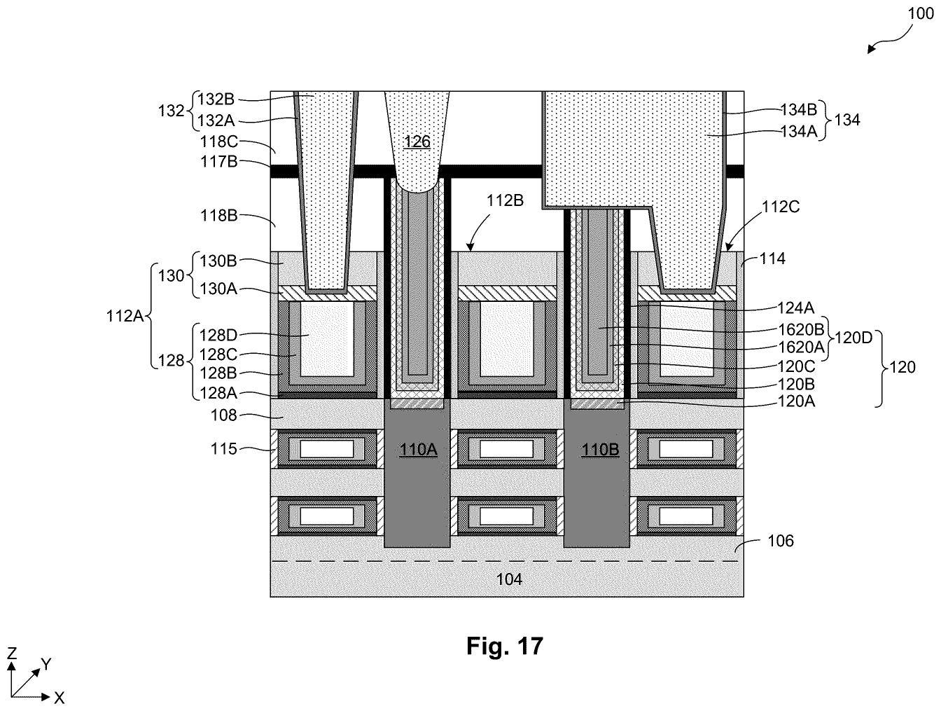

In some embodiments, the oxide removal process, the deposition process of second conductive nitride layer 1320, and the deposition process of first metal layer 1420 can be in-situ processes, which are performed without introducing vacuum breaks between the processes. After the formation of S/D contact structures 120, ESL 117B and ILD layer 118C can be formed, as shown in FIG. 17.

Referring to FIG. 2, in operation 220, a via structure is formed on one of the S/D contact structures. For example, as shown in FIG. 17, via structure 126 is formed though ILD layer 118C and ESL 117B and in S/D contact structure 120 on S/D region 110A.

Referring to FIG. 2, in operation 225, a gate contact structure is formed on a first one of the gate structures and a merged via-contact structure is formed on a second one of the S/D contact structures and on a second one of the gate structures. For example, as shown in FIG. 17, gate contact structure 132 is formed on gate structure 112A and merged via-contact structure 134 is formed on S/D region 110B and gate structure 112C at the same time.

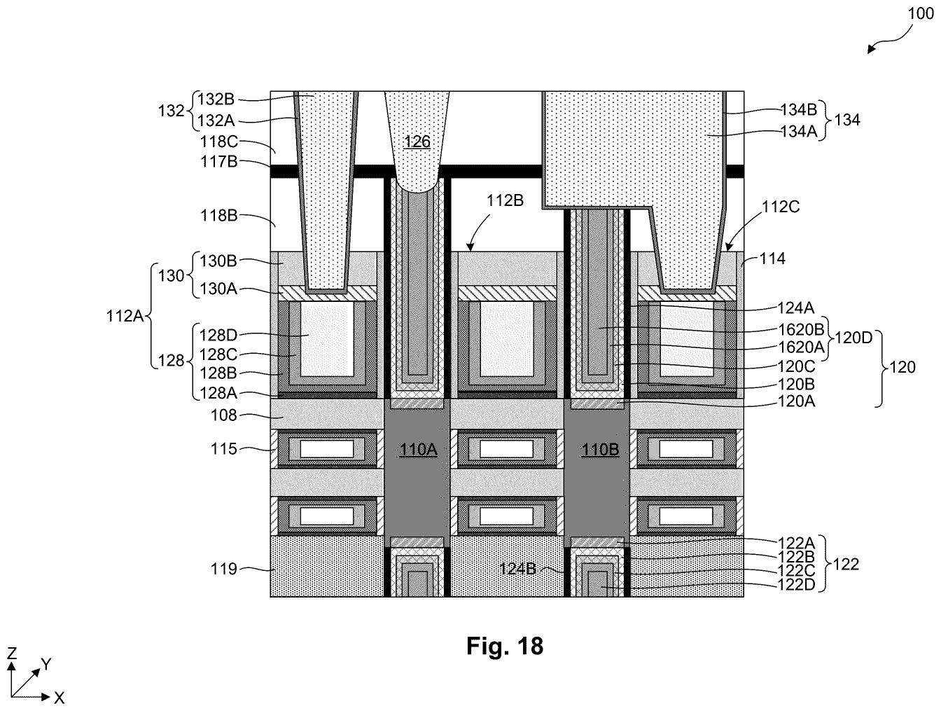

Referring to FIG. 2, in operation 230, S/D contact structures are formed on back-side surfaces of the S/D regions. For example, as shown in FIG. 18, S/D contact structures 122 are formed on back-side surfaces of S/D regions 110A and 110B. The formation of S/D contact structures 122 can include sequential operations of (i) removing fin bases 106 and portions of substrate 104 under S/D regions 110A and 110B to form openings (not shown), (ii) forming dielectric barrier layers 124B in the openings, and (iii) forming S/D contact structures 122 in the openings. The operations of forming silicide layers 122A, first diffusion barrier layers 122B, second diffusion barrier layers 122C, and contact plugs 122D of S/D contact structures 122 and dielectric barrier layers 124B can be similar to the operations of forming silicide layers 120A, first diffusion barrier layers 120B, second diffusion barrier layers 120C, and contact plugs 120D of S/D contact structures 120 and dielectric barrier layers 124A, as described in operation 215. After the formation of S/D contact structures 122, substrate 104 can be replaced with ILD layer 119, as shown in FIG. 18.

The present disclosure provides example methods (e.g. method 200) for minimizing contact resistance between contact structures and source/drain (S/D) regions in FETs (e.g., FET 100). In some embodiments, a S/D region (e.g., S/D regions 110A-110C) can be formed on a fin base (e.g., fin base 106) and a contact structure (e.g., S/D contact structures 120 and 122) can be formed on the S/D region. In some embodiments, the formation of the contact structure can include depositing a first diffusion barrier layer (e.g., first diffusion barrier layer 1020) in a contact opening (e.g., contact opening 742) on the S/D region, depositing a second diffusion barrier layer (e.g., second diffusion barrier layer 1320) on the first diffusion barrier layer, and depositing a conductive layer (e.g., metal layer 1520) on the second diffusion barrier layer. In some embodiments, the formation of the contact structure can further include performing an oxide removal process (also referred to as a “cleaning process”) on the first diffusion barrier layer prior to depositing the second diffusion barrier layer. The oxide removal process can remove a native oxide layer (e.g., native oxide layer 1044) and/or oxygen atoms from a top surface of the first diffusion barrier layer to reduce a concentration of oxygen atoms on the top surface of the first diffusion barrier layer to less than about 5 atomic % (e.g., about 0.1 atomic % to about 4.9 atomic %). The native oxide layer and/or the oxygen atoms on the top surface of the first diffusion barrier layer can be introduced due to a reaction between atmospheric oxygen and the material of the first diffusion barrier layer during a vacuum break between the deposition of the first and second diffusion barrier layers. The presence of the native oxide layer and/or the oxygen atoms at the interface between the first and second diffusion barrier layers can degrade the electrical conductivity between the contact structure and the S/D region. Thus, the oxide removal process can minimize the contact resistance between the contact structure and the S/D region.

In some embodiments, a method includes forming a nanostructured layer on a substrate, forming a gate structure surrounding the nanostructured layer, forming a S/D region adjacent to the nanostructured layer, forming a contact opening on the S/D region, depositing a first conductive layer in the contact opening using a first deposition process, performing a plasma etch process on the first conductive layer, depositing a second conductive layer on the first conductive layer using a second deposition process different from the first deposition process, and depositing a metal layer on the second conductive layer.

In some embodiments, a method includes forming a gate structure on a substrate, forming a S/D region adjacent to the gate structure, and forming a contact structure. The forming of the contact structure includes forming a contact opening on the S/D region, depositing a first nitride layer in the contact opening, removing a native oxide layer from a surface of the first nitride layer, depositing a second nitride layer on the first nitride layer, and depositing a metal layer on the second nitride layer.

In some embodiments, a semiconductor device includes a substrate, a nanostructured channel region disposed on the substrate, a gate structure surrounding the nanostructured channel region, a source/drain (S/D) region disposed adjacent to the nanostructured channel region, and a contact structure. The contact structure includes a first diffusion barrier layer disposed on the S/D region, a second diffusion barrier layer disposed on the first diffusion barrier layer, and a metal layer disposed on the second diffusion barrier layer. A concentration of oxygen atoms at an interface between the first and second diffusion barrier layers is less than about 5 atomic %.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a nanostructured layer on a substrate;
forming a gate structure surrounding the nanostructured layer;
forming a source/drain (S/D) region adjacent to the nanostructured layer;
forming a contact opening on the S/D region;
depositing a first conductive layer in the contact opening using a first deposition process;
performing a plasma etch process on the first conductive layer;
depositing a second conductive layer on the first conductive layer using a second deposition process different from the first deposition process; and
depositing a metal layer on the second conductive layer.

2. The method of claim 1, wherein depositing the first conductive layer comprises depositing a conductive nitride layer using a chemical vapor deposition process.

3. The method of claim 1, wherein depositing the second conductive layer comprises depositing a conductive nitride layer using an atomic layer deposition process.

4. The method of claim 1, wherein performing the plasma etch process comprises etching a native oxide layer from a surface of the first conductive layer.

5. The method of claim 1, wherein performing the plasma etch process comprises etching a native oxide layer from a surface of the first conductive layer using hydrogen radicals.

6. The method of claim 1, wherein performing the plasma etch process comprises etching a native oxide layer from a surface of the first conductive layer using a gas mixture comprising a concentration ratio of hydrogen to nitrogen of about 4:1 to about 6:1.

7. The method of claim 1, wherein performing the plasma etch process comprises etching a native oxide layer from a surface of the first conductive layer at a temperature of about 350° C. to about 450° C.

8. The method of claim 1, wherein depositing the first conductive layer and depositing the second conductive layer are performed ex-situ.

9. The method of claim 1, wherein performing the plasma etch process, depositing the second conductive layer, and depositing the metal layer are performed in-situ.

10. The method of claim 1, further comprising depositing an oxygen-free nitride layer in the contact opening prior to depositing the first conductive layer.

11. A method, comprising:
forming a gate structure on a substrate;
forming a source/drain (S/D) region adjacent to the gate structure; and
forming a contact structure, comprising:
forming a contact opening on the S/D region;
depositing a first nitride layer in the contact opening;
removing a native oxide layer from a surface of the first nitride layer;
depositing a second nitride layer on the first nitride layer; and
depositing a metal layer on the second nitride layer.

12. The method of claim 11, wherein depositing the first nitride layer comprises depositing a titanium nitride using a chemical vapor deposition process.

13. The method of claim 11, wherein depositing the second nitride layer comprises depositing a titanium nitride using an atomic layer deposition process.

14. The method of claim 11, wherein removing the native oxide layer comprises performing an etch process using a gas mixture comprising a concentration ratio of hydrogen to nitrogen of about 4:1 to about 6:1.

15. The method of claim 11, wherein removing the native oxide layer comprises performing an etch process at a temperature of about 350° C. to about 450° C.

16. The method of claim 11, wherein removing the native oxide layer, depositing the second nitride layer, and depositing the metal layer are performed in-situ.

17. A semiconductor device, comprising:
a substrate;
a nanostructured channel region disposed on the substrate;
a gate structure surrounding the nanostructured channel region;
a source/drain (S/D) region disposed adjacent to the nanostructured channel region; and
a contact structure, comprising:
a first diffusion barrier layer disposed on the S/D region;
a second diffusion barrier layer disposed on the first diffusion barrier layer, wherein a concentration of oxygen atoms at an interface between the first and second diffusion barrier layers is less than about 5 atomic %; and
a metal layer disposed on the second diffusion barrier layer.

18. The semiconductor device of claim 17, further comprising an oxygen-free nitride layer surrounding the contact structure.

19. The semiconductor device of claim 17, wherein the first diffusion barrier layer comprises a titanium silicon nitride layer.

20. The semiconductor device of claim 17, wherein the second diffusion barrier layer comprises a titanium nitride layer.
